(19) United States
(12) Patent Application Publication
(10) Pub. No.: US 2008/0283925 A1
(43) Pub. Date: Nov. 20, 2008

(54) Multi-Fin Component Arrangement and Method for Manufacturing a Multi-Fin Component Arrangement

(76) Inventors: Joerg Berthold, Muenchen (DE); Christian Pacha, Muenchen (DE); Klaus Schruefer, Baldham (DE); Klaus Von Arnim, Muenchen (DE)

Correspondence Address: SLATER & MATSIL LLP, 17950 PRESTON ROAD, SUITE 1000, DALLAS, TX, 75252, US

(21) Appl. No.: 12/124,369

(22) Filed: May 21, 2008

Related U.S. Application Data
(63) Continuation of application No. PCT/DE2006/002010, filed on Nov. 16, 2006.

(30) Foreign Application Priority Data
Nov. 21, 2005 (DE) 10 2005 055 299.4
Jun. 12, 2006 (DE) 10 2006 027 178.5

(51) Int. Cl. H01L 27/088; H01L 21/82

(52) U.S. Cl. 257/368; 438/400; 257/E27.06; 257/E21.616

(57) ABSTRACT

In a first embodiment, a multi-fin component arrangement has a plurality of multi-fin component partial arrangements. Each of the multi-fin component partial arrangements has a plurality of electronic components, which electronic components have a multi-fin structure. At least one multi-fin component partial arrangement has at least one dummy structure, which at least one dummy structure is formed between at least two of the electronic components formed in the at least one multi-fin component partial arrangement. The dummy structure is formed in such a way that electrical characteristics of the electronic components formed in the multi-fin component partial arrangements are adapted to one another.

This application is a continuation of co-pending International Application No. PCT/DE2006/002010, filed Nov. 16, 2006, which designated the United States and was not published in English, and which is based on German Application No. 10 2005 055 299.4 filed Nov. 21, 2005 and German Application No. 10 2006 027 178.5 filed Jun. 12, 2006, which applications are incorporated herein by reference.

### TECHNICAL FIELD

The invention relates to a multi-fin component arrangement and a method for manufacturing a multi-fin component arrangement.

### BACKGROUND

Novel transistor architectures based on so-called multi-gate field effect transistors (MuGFET), fin field effect transistors (FinFET), or double-gate field effect transistors (double-gate FET) are currently being developed for future sub-45-nm CMOS technologies (Complementary Metal Oxide Semiconductor), see, for example, Bin Yu, et al., “FinFET scaling to 10 nm gate length”, Electron Devices Meeting 2002, IEDM '02, Digest. International, pp. 251-254; and Fu-Liang Yang, et al., “35 nm CMOS FinFETs”, 2002 Symposium on VLSI Technology, Digest of Technical Papers, pp. 104-105.

One advantage of the new transistors over planar bulk MOSFETs (metal oxide semiconductor FET) consists in the improved control of the short-channel effects as a result of a symmetrical arrangement of a plurality of transistor gates. The two technologically favored arrangements include either two lateral gates (FinFET) or two lateral gates and one additional gate on the upper top area of the silicon fin (triple-gate FET, see B. Doyle, et al., “Tri-Gate Fully-Depleted CMOS Transistors: Fabrication, Design and Layout”, 2003 Symposium on VLSI Technology, Digest of Technical Papers, pp. 133-134). This correspondingly results in two or three channel zones for current transport. The silicon fin is referred to as just a “fin”.

FIG. 1A shows a schematic illustration of a typical fin field effect transistor 100 having a fin structure or fin 101, which fin 101 is formed on a buried oxide layer 102 (buried oxide, BOX). The fin 101 has a source region 103 and a drain region 104. A gate structure 105 is formed on the fin 101, the gate structure being electrically insulated from the fin 101 by a gate oxide 106. The gate oxide 106 is formed with a very small thickness on the two side areas, and the gate oxide 106 has a larger thickness on the upper top area of the fin 101. As a result, clearly two lateral gates are formed which are used to control the conductivity of the channel region formed between the source region 103 and the drain region 104 (concealed by the gate oxide 106 and the gate structure 105). In FIG. 1A, the height of the fin structure 101 is furthermore identified by the double-headed arrow “H_{Fin}”.

FIG. 1B shows a schematic illustration of a triple-gate field effect transistor 150 having a fin structure 101. In contrast to the FinFET 100, in the case of the triple-gate FET 150, the gate oxide 106 has the same small thickness on the upper top area of the fin structure 101 as on the two side areas. As a result, the gate structure 105 forms three gates, i.e., two lateral gates and one additional gate formed on the upper top area of the fin structure 101, which are used to control the conductivity of the channel region. In FIG. 1B, furthermore, the thickness of the fin structure 101 is identified by the double arrow “W_{Fin}”, and the length of the gate structure 105 is identified by the double-headed arrow “L_{Gate}”.

In order to ensure a good electrostatic control via the channel zones, the thickness W_{Fin} of a fin must be significantly less than the length L_{Gate} of the gate, e.g., W_{Fin}=30 nm for a gate length of L_{Gate}=45 nm, i.e. L_{Gate}/W_{Fin}≈3/2.

Together with a typical fin height of H_{Fin}=60 nm, for an individual fin this gives rise to an effective transistor width of W_{eff}=2 H_{Fin}+W_{Fin}=150 nm for a triple-gate FET and of W_{eff}=2 H_{Fin}=120 nm for a FinFET transistor type. FIG. 1C schematically illustrates the calculation of the effective transistor width for a triple-gate FET having a fin structure 101. In circuit applications, transistors having a high current driver capability are often required, such that so-called multi-fin structures are used instead of an individual fin, in which structures a plurality of fins are connected in parallel, see e.g. Bin Yu, et al., “FinFET scaling to 10 nm gate length”, Electron Devices Meeting 2002, IEDM '02, Digest. International, pp. 251-254; and Fu-Liang Yang, et al., “35 nm CMOS FinFETs”, 2002 Symposium on VLSI Technology, Digest of Technical Papers, pp. 104-105.

FIG. 2A shows a micrograph taken by scanning electron microscopy (SEM) of a multi-fin structure 200 having a plurality of parallel fin structures (fins) 201, a first source/drain region 203, a second source/drain region 204 and a gate structure 205 formed over the fins 201. In the SEM micrograph, the fins 201 are largely concealed by the gate structure 205. FIG. 2A furthermore shows electrical contacts 207, which electrical contacts 207 are formed on the first source/drain region 203 and on the second source/drain region 204.

A multi-fin structure yields a total current which is proportional to the number of fins connected in parallel. A further important characteristic quantity for the packing density, i.e., for an area-efficient MuGFET-CMOS technology, is therefore the pitch P_{Fin} (clearly the distance between two parallel fins) with which multi-fin structures can be produced.

FIG. 1C schematically shows the pitch P_{Fin} for a multi-fin structure 170, which multi-fin structure 170 has a plurality of parallel fin structures 101. The height H_{Fin} and the thickness W_{Fin} of a fin structure 101 are furthermore shown.

By choosing a suitable aspect ratio H_{Fin}/W_{Fin} and a narrow pitch P_{Fin}, it is technologically possible to obtain a large effective transistor width W_{eff} on a small basic area. The possible gain in area compared with a bulk CMOS technology can be described by the ratio W_{eff}/P_{Fin}. For a pitch P_{Fin}=100 nm, therefore, this would result, e.g., in an area gain of W_{eff}/P_{Fin}=150 nm/100 nm=1.5 for triple-gate FETs and of W_{eff}/P_{Fin}=120 nm/100 nm=1.2 for FinFETs.

For the reason mentioned above, the manufacturing of the fins (requirement made of the lithography, etching process, etc.) is more demanding than the manufacturing of the transistor gate. In particular, it must be ensured that the interspaces within multi-fin structures have as far as possible no greatly pronounced roundings, but rather rectangular forms that are as uniform as possible.

No multi-gate CMOS technologies are known from the prior art to date. Work on the interface between circuits and multi-gate CMOS technologies is currently being started worldwide. However, first prototypes show the relevance of suitable arrangements for series transistors in multi-fin structures since the following difficulties occur:

(a) A good control of the short-channel effects requires very thin fins. A disadvantage of the thin fins, however, is high parasitic resistances on account of the small cross-sectional areas W_{Fin}×H_{Fin}. One technological approach for reducing the parasitic resistance consists in using selective epitaxy to thicken the fins and then to silicide them (e.g., NiSi). This is associated with a high outlay, however.

(b) In CMOS circuit design, in general any desired transistor arrangements including parallel and series circuits are used to realize CMOS logic gates, for example. In order to obtain an electrical transistor behavior of the same type independently of the arrangements, in the highly complex three-dimensional multi-gate CMOS structures, each fin should have surroundings that are, as far as possible, identical in type. That is to say that the parasitic resistances in the fins and the roundings in the openings within the multi-fin structures should be, as far as possible, independent of the electrical circuit arrangement.

The facts mentioned under (b) are illustrated by way of example in the SEM images in FIG. 2B and FIG. 2C. The images show the geometrical dependence of the opening within different multi-fin structures, wherein FIG. 2B shows an excerpt from a multi-fin structure 210 having a plurality of fins 201, in which multi-fin structure 210 the distance between the first source/drain region 203 and the second source/drain region 204 is approximately 290 nm, while FIG. 2C shows an excerpt from a multi-fin structure 220 having a plurality of fins 201, in which multi-fin structure 220 the distance between the first source/drain region 203 and the second source/drain region 204 is approximately 490 nm. The roundings in the openings within the multi-fin structures 210 and 220 can clearly be discerned in FIG. 2B and FIG. 2C.

The roundings in the openings within the multi-fin structures can be minimized with the aid of a correction method (optical proximity correction, OPC). However, individual rules have to be created in the context of an OPC method for each process, and creating a complete mask set for the lithography process therefore takes a very long time (typically weeks).

FIGS. 3A to 4C show layout illustrations for two different CMOS logic gates based on multi-gate transistors in accordance with the prior art.

FIG. 3A, FIG. 3B and FIG. 3C show layout illustrations of a NAND logic gate 350 having two electrical inputs (NAND2 gates) in accordance with the prior art, wherein a first electrical logic input signal “A” is provided at a first electrical input A and a second electrical logic input signal “B” is provided at a second electrical input B. The NAND logic gate 350 furthermore has an electrical output Z, an electrical logic output signal “Z= A̅B̅” being provided at the electrical output Z.

FIG. 3A shows the layout to the first metallization level (metal 1), and FIG. 3B shows the layout up to and including gate and contact hole level (Poly/CA), wherein the positions of individual contact holes are represented by the squares 330. FIG. 3C shows the layout after the manufacturing of the fins and source/drain regions.

The NAND logic gate 350 has a PMOS parallel circuit 351 having a first PMOS multi-gate field effect transistor 352 and a second PMOS multi-gate field effect transistor 353 connected in parallel with the first PMOS multi-gate field effect transistor 352. Furthermore, the NAND logic gate 350 has an NMOS series circuit 354 having a first NMOS multi-gate field effect transistor 355 and a second NMOS multi-gate field effect transistor 356 connected in series with the first NMOS multi-gate field effect transistor 355.

The PMOS multi-gate field effect transistors 352 and 353, respectively, have a first multi-fin structure 300a having four fins 301a connected in parallel, and the NMOS multi-gate field effect transistors 355 and 356, respectively, have a second multi-fin structure 300b having four fins 301b connected in parallel.

The first PMOS multi-gate field effect transistor 352 and the first NMOS multi-gate field effect transistor 355 have a common first gate 305a, which is electrically coupled to the second electrical input B of the NAND logic gate 350. Furthermore, the second PMOS multi-gate field effect transistor 353 and the second NMOS multi-gate field effect transistor 356 have a common second gate 305b, which is electrically coupled to the first electrical input A of the NAND logic gate 350.

A first source/drain region 352a of the first PMOS multi-gate field effect transistor 352 is connected to the electrical potential V_{DD} via a first connection region 307a, and a first source/drain region 353a of the second PMOS multi-gate field effect transistor 353 connected in parallel with the first PMOS multi-gate field effect transistor 352 is connected to the electrical potential V_{DD} via a second connection region 308a. A second source/drain region 352b of the first PMOS multi-gate field effect transistor 352 and a second source/drain region 353b of the second PMOS multi-gate field effect transistor 353 are electrically coupled to the electrical output Z of the NAND logic gate 350 via a third connection region 309a.

A first source/drain region 355a of the first NMOS multi-gate field effect transistor 355 is connected to the electrical potential V_{SS} via a fourth connection region 307b, and a second source/drain region 355b of the first NMOS multi-gate field effect transistor 355 is electrically coupled to a first source/drain region 356a of the second NMOS multi-gate field effect transistor 356 connected in series with the first NMOS multi-gate field effect transistor 355. A second source/drain region 356b of the second NMOS multi-gate field effect transistor 356 is electrically coupled to the electrical output Z of the NAND logic gate 350 via a fifth connection region 308b.

In the NMOS series circuit 354, four individual fins 301b are connected in parallel in the NMOS pull-down path. FIGS. 3A to 3C illustrate that the fins 301b of the NMOS series circuit 354 have different surroundings than the fins 301a of the PMOS parallel circuit 351. By way of example, the interspaces 362b between the fins 301b of the second multi-fin structure 300b formed in the NMOS series circuit 354, along the longitudinal direction of the fins 301b (that is to say along the connecting axis between the two connection regions 307b and 308b), have a significantly larger extent than the interspaces 362a between the fins 301a of the first multi-fin structure 300a formed in the PMOS parallel circuit 351 (see FIG. 3C).

Moreover, the NMOS series circuit 354 has a thin silicon zone 361b formed between the first gate 305a and the second gate 305b, the silicon zone, along the longitudinal direction of the fins 301b, having a significantly larger extent (approximately 10-12 squares) than the thin silicon zones 360b, which thin silicon zones 360b are formed between the fourth connection region 307b and the first gate 305a and, respectively, between the fifth connection region 308b and the second gate 305b, see FIG. 3B. The greatly extended thin silicon zone 361b has a high parasitic resistance. In the complementary PMOS parallel circuit 351, by contrast, the corresponding thin silicon zones 360a all have the same small extent along the longitudinal direction of the fins 301a, such that a lower parasitic resistance occurs here.

On account of the different extents of the thin silicon zones, the NAND logic gate 350 with a conventional layout therefore has the disadvantage of non-uniform parasitic resistances or capacitances.

FIG. 4A, FIG. 4B and FIG. 4C show, analogously to FIGS. 3A to 3C, layout illustrations of a NOR logic gate 450 having two electrical inputs (NOR2 gate) in accordance with the prior art, wherein a first electrical logic input signal “A” is provided at a first electrical input A and a second electrical logic input signal “B” is provided at a second electrical input B. The NOR logic gate 450 furthermore has an electrical output Z, an electrical logic output signal “Z= A̅+̅B̅”, being provided at the electrical output Z.

FIG. 4A shows the layout up to the first metallization level (metal 1), and FIG. 4B shows the layout up to and including gate and contact hole level (poly/CA), wherein the positions of individual contact holes are represented by the squares 430. FIG. 4C shows the layout after the manufacturing of the fins and source/drain regions.

The NOR logic gate 450 has a PMOS series circuit 451 having a first PMOS multi-gate field effect transistor 452 and a second PMOS multi-gate field effect transistor 453 connected in series with the first PMOS multi-gate field effect transistor 452. Furthermore, the NOR logic gate 450 has an NMOS parallel circuit 454 having a first NMOS multi-gate field effect transistor 455 and a second NMOS multi-gate field effect transistor 456 connected in parallel with the first NMOS multi-gate field effect transistor 455.

The two PMOS multi-gate field effect transistors 452, 453 have a first multi-fin structure 400a having eight fins 401a connected in parallel, and the two NMOS multi-gate field effect transistors 455, 456 have a second multi-fin structure 400b having two fins 401b connected in parallel.

The first PMOS multi-gate field effect transistor 452 and the first NMOS multi-gate field effect transistor 455 have a common first gate 405a, which is electrically coupled to the second electrical input B of the NOR logic gate 450. Furthermore, the second PMOS multi-gate field effect transistor 453 and the second NMOS multi-gate field effect transistor 456 have a common second gate 405b, which is electrically coupled to the first electrical input A of the NOR logic gate 450.

A first source/drain region 452a of the first PMOS multi-gate field effect transistor 452 is connected to the electrical potential V_{DD} via a first connection region 407a, and a second source/drain region 452b of the first PMOS multi-gate field effect transistor 452 is electrically coupled to a first source/drain region 453a of the second PMOS multi-gate field effect transistor 453 connected in series with the first PMOS multi-gate field effect transistor 452. A second source/drain region 453b of the second PMOS multi-gate field effect transistor 453 is electrically coupled to the electrical output Z via a second connection region 408a.

A first source/drain region 455a of the first NMOS multi-gate field effect transistor 455 is connected to the electrical potential V_{SS} via a third connection region 407b, and a first source/drain region 456a of the second NMOS multi-gate field effect transistor 456 connected in parallel with the first NMOS multi-gate field effect transistor 455 is connected to the electrical potential V_{SS} via a fourth connection region 408b. A second source/drain region 455b of the first NMOS multi-gate field effect transistor 455 and a second source/drain region 456b of the second NMOS multi-gate field effect transistor 456 are electrically coupled to the electrical output Z of the NOR logic gate 450 via a fifth connection region 409b.

FIGS. 4A to 4C illustrate that the fins 401a of the PMOS series circuit 451 have different surroundings than the fins 401b of the NMOS parallel circuit 454. By way of example, the interspaces 462a between the fins 401a of the first multi-fin structure 400a formed in the PMOS series circuit 451, along the longitudinal direction of the fins 401a (or along the connecting axis between the two connection regions 407a and 408a), have a significantly larger extent than the interspaces 462b between the fins 401b of the second multi-fin structure 400b formed in the NMOS parallel circuit 454 (see FIG. 4C).

Moreover, the PMOS series circuit 451 has a thin silicon zone 461a formed between the first gate 405a and the second gate 405b, the thin silicon zone, along the longitudinal direction of the fins 401a, having a significantly larger extent than the thin silicon zones 460b, which thin silicon zones 460b are formed between the first connection region 407a and the first gate 405a and, respectively, between the second connection region 408a and the second gate 405b, see FIG. 4B. The greatly extended thin silicon zone 461a has a high parasitic resistance. In the complementary NMOS parallel circuit 454, by contrast, the corresponding thin silicon zones 460b all have the same small extent along the longitudinal direction of the fins 401b, such that a lower parasitic resistance occurs here.

On account of the different extents of the thin silicon zones, the NOR logic gate 450 with a conventional layout also has the disadvantage of non-uniform parasitic resistances or capacitances.

### SUMMARY OF THE INVENTION

Aspects of the invention provide a production-friendly, regular arrangement of electronic components (e.g., transistors) in multi-fin structures in which the abovementioned disadvantages are at least partly avoided or reduced.

In a first embodiment, a multi-fin component arrangement has a plurality of multi-fin component partial arrangements. Each of the multi-fin component partial arrangements has a plurality of electronic components, which electronic components have a multi-fin structure. At least one multi-fin component partial arrangement has at least one dummy structure, which at least one dummy structure is formed between at least two of the electronic components formed in the at least one multi-fin component partial arrangement. The dummy structure is formed in such a way that electrical characteristics of the electronic components formed in the multi-fin component partial arrangements are adapted to one another.

In a method embodiment a plurality of multi-fin component partial arrangements are formed. Each of the multi-fin component partial arrangements has a plurality of electronic components, which electronic components have a multi-fin structure. Furthermore, at least one dummy structure is formed in at least one multi-fin component partial arrangement, which at least one dummy structure is formed between at least two of the electronic components formed in the at least one multi-fin component partial arrangement, wherein the at least one dummy structure is formed in such a way that electrical characteristics of the electronic components formed in the multi-fin component partial arrangements are adapted to one another with the aid of the at least one dummy structure.

One aspect of the invention can be seen in the fact that at least one dummy structure is formed in a multi-fin component arrangement, which multi-fin component arrangement has a plurality of electronic components. In this context, a dummy structure is understood to mean a functionless structure, in the sense that the dummy structure is not necessary for ensuring the functionality of the electronic components formed in the multi-fin component arrangement. In other words, the electronic components formed in the multi-fin component arrangement are fully functional either with or without a dummy structure formed in the multi-fin component arrangement.

However, the functionality of the electronic components is also not restricted by the presence of the dummy structure. Rather, one advantage of the invention can be seen in particular in the fact that forming a dummy structure has a positive influence on the functionality of the electronic components formed in a multi-fin component arrangement since, by way of example, electrical characteristics of the electronic components formed in the multi-fin component arrangement are adapted or matched to one another.

In one configuration of the invention, the at least one dummy structure is formed in such a way that it adapts parasitic resistances of the electronic components formed in the multi-fin component partial arrangements to one another. In other words, what is achieved by forming the dummy structure is that the electronic components formed in the multi-fin component partial arrangements have identical or at least similar parasitic resistances.

In another configuration of the invention, the at least one dummy structure is formed in such a way that it adapts parasitic capacitances of the electronic components formed in the multi-fin component partial arrangements to one another. In other words, what is achieved by forming the dummy structure is that the electronic components formed in the multi-fin component partial arrangements have identical or at least similar parasitic capacitances.

In accordance with another configuration of the invention, the multi-fin structures of the electronic components formed in the multi-fin component partial arrangements have at least two fin structures or fins, which fin structures or fins can be connected in parallel.

The individual fin structures or fins of a multi-fin structure can have a length of 60 nm to 800 nm, a width of 10 nm to 50 nm, and a height of 20 nm to 80 nm.

Furthermore, the fin structures can have a pitch of 20 nm to 200 nm. In other words, the distance between two parallel fin structures can be 20 nm to 200 nm.

Another configuration of the invention provides for the dummy structure to be formed as a block structure, which block structure is formed at least partly below at least one of the multi-fin structures of the electronic components formed in the multi-fin component partial arrangements.

In other words, a dummy structure formed as a block structure can be formed at least partly below a multi-fin structure of an individual electronic component, or the block structure can be formed at least partly below the multi-fin structures of a plurality of electronic components. In both cases, the dummy structure can be formed at least partly below the individual fin structures or fins of the at least one multi-fin structure.

In accordance with another configuration of the invention, a dummy structure formed as a block structure can include silicon material. To put it another way, the dummy structure is formed as a silicon block in this configuration.

One aspect of the invention can be seen in the fact that with the aid of a dummy structure the individual fin structures or fins of a multi-fin component arrangement are connected in such a way that they have a common contact zone with which electrical contact is not made via external connections such as, for example, VDD, VSS or inputs and outputs (so-called “stacked node”).

Another configuration of the invention provides for at least one of the electronic components formed in the multi-fin component partial arrangements to be formed as a field effect transistor.

In accordance with another configuration of the invention, at least one multi-fin component partial arrangement has at least two electronic components connected in parallel. The at least two electronic components connected in parallel can be, for example, two field effect transistors connected in parallel.

In another configuration of the invention, at least one multi-fin component partial arrangement has at least two electronic components connected in series. The at least two electronic components connected in series can be, for example, two field effect transistors connected in series.

In accordance with another configuration, the at least one dummy structure is formed between at least two of the electronic components connected in series, for example, between two field effect transistors connected in series.

The at least one dummy structure can be formed between the gate structures or gates of at least two series-connected field effect transistors of at least one multi-fin component partial arrangement.

In another configuration of the invention, at least one of the field effect transistors is formed as a fin field effect transistor and/or as a multi-gate field effect transistor.

A field effect transistor formed as a multi-gate field effect transistor can be formed as a double-gate field effect transistor or as a triple-gate field effect transistor or as a surrounding-gate field effect transistor.

In accordance with another configuration of the invention, at least one of the field effect transistors is formed as a MOS field effect transistor.

Another configuration of the invention provides for a multi-fin component arrangement to be formed as a CMOS circuit arrangement, wherein in at least one multi-fin component partial arrangement, at least one of the electronic components formed as a MOS field effect transistor is formed as a PMOS field effect transistor, and/or wherein in at least one multi-fin component partial arrangement, at least one of the electronic components formed as a MOS field effect transistor is formed as an NMOS field effect transistor.

A multi-fin component arrangement formed as a CMOS circuit arrangement can be formed as a logic gate circuit, wherein all elementary logic gates or logic gate functions can be realized. In addition, complex logic gates can also be realized.

The logic gate circuit can be formed, for example, as NAND logic gate having at least two inputs, as NOR logic gate having at least two inputs, as C²MOS logic gate, as CMOS transmission gate or as AND-OR inverting logic gate (AND-OR inverter, AOI), i.e., as logic gate with the logic function Z= A̅B̅+̅C̅D̅.

Another configuration of the invention provides for a dummy structure formed as a block structure to have a size, which size is suitable for forming at least one contact hole.

One aspect of the invention can be seen in the fact that a layout-and technology-friendly arrangement of electronic components with multi-fin structure, e.g., transistors with multi-fin structure (multi-fin transistors), is provided by a multi-fin component arrangement. The source regions and the drain regions of a multi-fin structure are in this case identical for series and parallel circuits of multi-fin structures, that is to say that each transistor has a uniform layout independently of its circuitry connections and surroundings.

One basic idea of the invention can be seen in the fact that a dummy structure, e.g., a silicon block, can be placed in each case between two series-connected multi-fin transistors, wherein the size of the dummy structure can be chosen in such a way that a contact hole can be positioned as in the complementary parallel circuit.

The multi-fin component arrangement can be formed as a CMOS logic circuit. Since CMOS logic circuits are always constructed from complementary NMOS arrangements and PMOS arrangements (wherein the PMOS arrangement can correspond to one multi-fin component partial arrangement of the multi-fin component arrangement and the NMOS arrangement can correspond to another multi-fin component partial arrangement of the multi-fin component arrangement), and since the gate structures or gates are embodied as a purely vertical structure in sub-90-nm technologies, forming the dummy structure does not result in an additional area requirement. To put it another way, no additional area is required as a result of forming the dummy structure in a multi-fin component arrangement formed as a CMOS circuit.

One advantage of the invention can be seen in the fact that in the case of a multi-fin component arrangement, forming at least one dummy structure results in a fully symmetrical transistor arrangement at the level of the fins. This means that all the transistors have identical connection zones at the source and drain. This in turn results in identical parasitic resistances and/or capacitances for all the transistors. By way of example, the parasitic resistances and/or capacitances that result for transistors connected in series are the same as those for transistors connected in parallel.

In the case of conventional multi-fin arrangements, the biggest proportion of the parasitic resistance arises in the zones between two transistor gates, which zones have the thin fins of the fin structures (see FIG. 3B and FIG. 4B). The fin structures can be formed from silicon; therefore, the zones with thin fins or fin structures between two transistor gates are also referred to hereinafter as thin silicon zones. As an alternative, however, the fin structures or the thin fins can also include other semiconductor materials.

A further advantage of the invention can be seen in the fact that in the case of a multi-fin component arrangement, the extent of the thin silicon zone along the longitudinal direction of the fin structures is greatly reduced in comparison with conventional arrangements, and the parasitic resistance is thus reduced.

In 32-nm CMOS technologies, strain effects are sought for increasing the charge carrier mobility. The strain effects can be produced, for example, in a targeted manner by forming strained silicon layers on silicon-on-insulator (SOI) substrates or by so-called cap layers. In this connection, a further advantage of the invention can be seen in the fact that an identical component arrangement or component environment (e.g., of multi-fin transistors) in a multi-fin component arrangement has the result that strain effects always affect the electrical component parameters in the same way. This simplifies both the process optimization and process control and the modeling and parameter extraction.

With regard to an OPC correction (optical proximity correction), the identical multi-fin structures simplify the generation of the mask data for lithography processes and etching processes since, by way of example, the number and diversity of the transistor arrangements occurring in logic circuits are reduced with the aid of the invention.

A further advantage of the invention can therefore be seen in the fact that the invention affords improvements with regard to a so-called design for manufacturability (DFM).

### BRIEF DESCRIPTION OF THE DRAWINGS

Exemplary embodiments of the invention are illustrated in the figures and are explained in more detail below. In the figures, identical elements are provided with identical reference symbols. Apart from the scanning electron microscopy images in FIGS. 2A, 2B and 2C, the illustrations shown in the figures are depicted in schematic fashion and therefore not as true to scale.

FIG. 1A shows the construction of a fin field effect transistor in accordance with the prior art;

FIG. 1B shows the construction of a triple-gate field effect transistor in accordance with the prior art;

FIG. 1C shows an illustration of relevant dimensions in the case of a multi-fin structure;

FIG. 2A shows a micrograph taken by scanning electron microscopy of a multi-fin structure;

FIG. 2B and FIG. 2C show the geometrical dependence of the opening within different multi-fin structures on the basis of scanning electron microscopy images;

FIGS. 3A to 3C show layout illustrations of a NAND logic gate in accordance with the prior art;

FIGS. 4A to 4C show layout illustrations of a NOR logic gate in accordance with the prior art;

FIGS. 5A to 5C show a multi-fin component arrangement in accordance with a first exemplary embodiment of the invention;

FIGS. 6A to 6C show a multi-fin component arrangement in accordance with a second exemplary embodiment of the invention;

FIGS. 7A and 7B show a multi-fin component arrangement in accordance with a third exemplary embodiment of the invention;

FIG. 7C shows a transistor circuit diagram for a C²MOS logic gate;

FIGS. 8A and 8B show a multi-fin component arrangement in accordance with a fourth exemplary embodiment of the invention;

FIG. 8C shows a transistor circuit diagram for a transmission gate;

FIGS. 9A and 9B show a multi-fin component arrangement in accordance with a fifth exemplary embodiment of the invention; and

FIG. 9C shows a transistor circuit diagram for an AND-OR inverting logic gate.

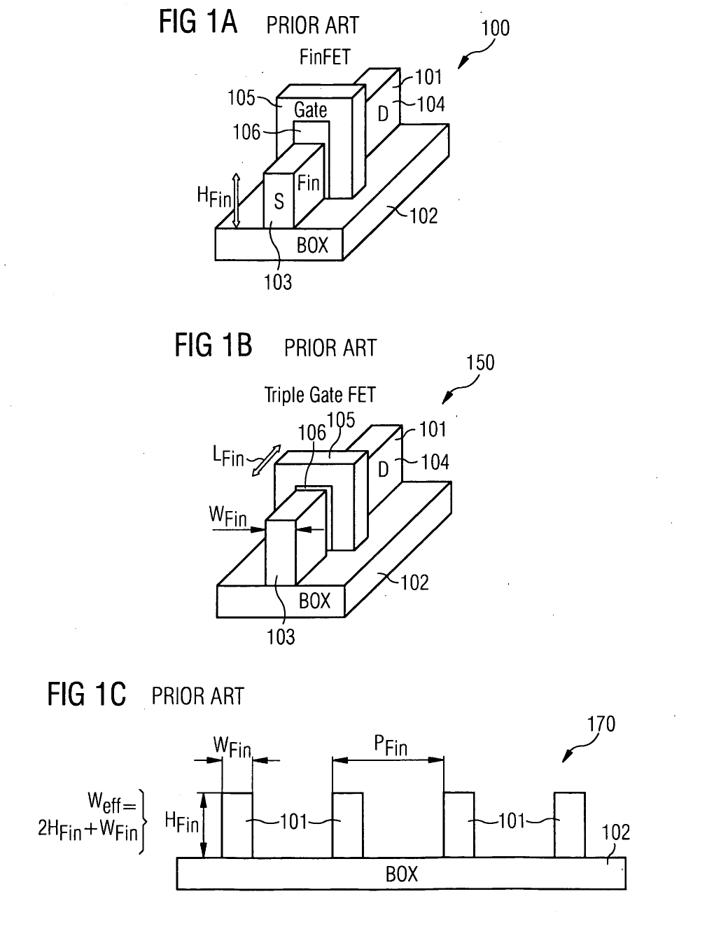

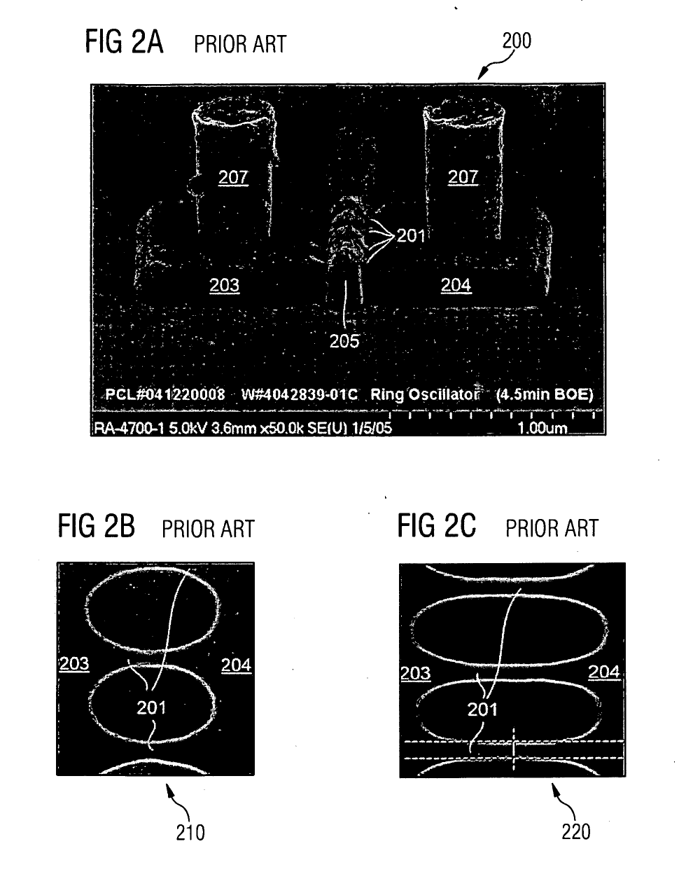

### DETAILED DESCRIPTION OF ILLUSTRATIVE EMBODIMENTS

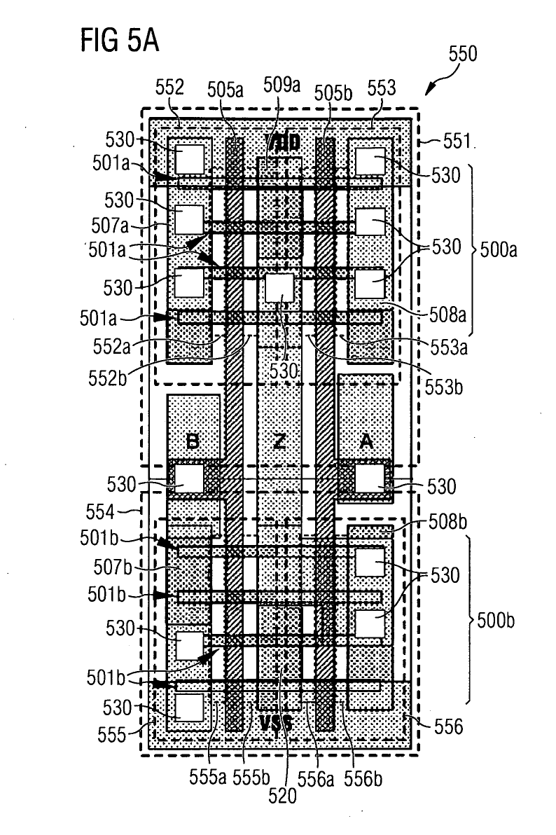

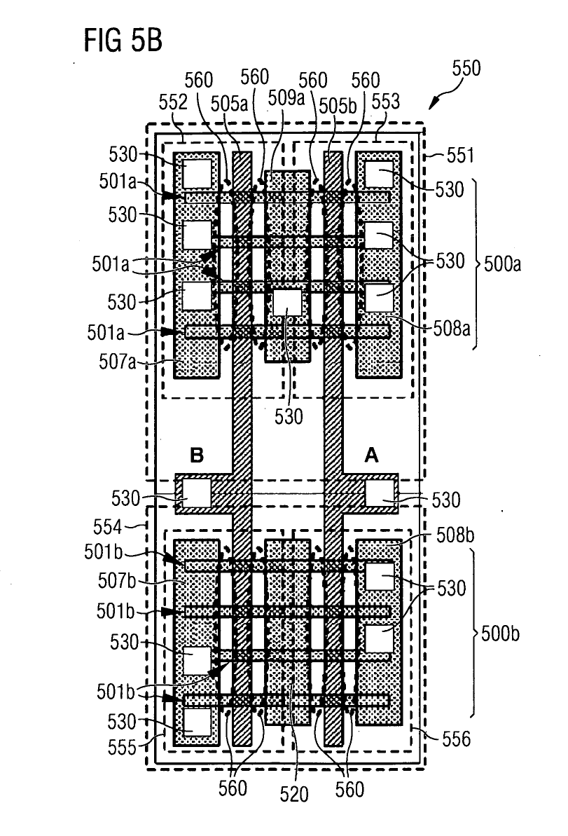

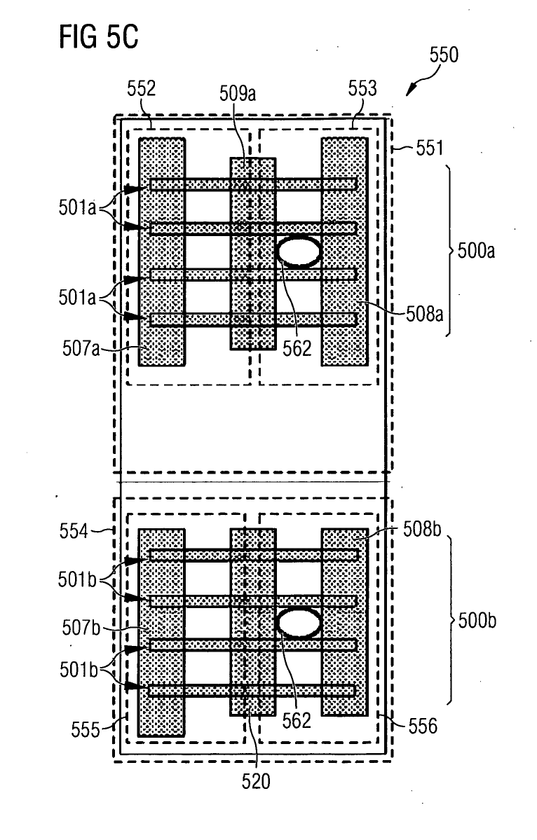

FIG. 5A, FIG. 5B and FIG. 5C show a multi-fin component arrangement 550 in accordance with a first exemplary embodiment of the invention. The multi-fin component arrangement 550 is formed as a NAND logic gate, having two electrical inputs (NAND2 logic gate), wherein a first electrical logic input signal “A” is provided at a first electrical input A and a second electrical logic input signal “B” is provided at a second electrical input B. The multi-fin component arrangement 550 formed as a NAND logic gate furthermore has an electrical output Z, an electrical logic output signal “Z= A̅B̅” being provided at the electrical output.

FIG. 5A, FIG. 5B and FIG. 5C show layout illustrations of the multi-fin component arrangement 550 formed as a NAND logic gate. FIG. 5A shows the layout up to the first metallization level (metal 1), and FIG. 5B shows the layout up to and including gate and contact hole level (poly/CA), wherein the positions of individual contact holes are represented by the squares 530. FIG. 5C shows the layout after the manufacturing of the fins and source/drain regions.

The multi-fin component arrangement 550 has a first multi-fin component partial arrangement 551 and a second multi-fin component partial arrangement 554, wherein the first multi-fin component partial arrangement 551 is formed as a PMOS parallel circuit and the second multi-fin component partial arrangement 554 is formed as an NMOS series circuit.

The first multi-fin component partial arrangement 551 formed as a PMOS parallel circuit has two electronic components 552 and 553 formed as field effect transistor, which electronic components 552 and 553 have a common first multi-fin structure 500a. The first multi-fin component partial arrangement 551 has a first PMOS field effect transistor 552 and a second PMOS field effect transistor 553 connected in parallel with the first PMOS field effect transistor 552.

The second multi-fin component partial arrangement 554 formed as an NMOS series circuit has two electronic components 555 and 556 formed as field effect transistors, which electronic components 555 and 556 have a common second multi-fin structure 500b. The second multi-fin component partial arrangement 554 has a first NMOS field effect transistor 555 and a second NMOS field effect transistor 556 connected in series with the first NMOS field effect transistor 555.

The first multi-fin structure 500a has four fin structures or fins 501a connected in parallel, and the second multi-fin structure 500b has four fin structures or fins 501b connected in parallel.

Both the PMOS field effect transistors 552, 553 and the NMOS field effect transistors 555, 556 can be formed as fin field effect transistor or as multi-gate field effect transistor (for example double-gate FET, triple-gate FET, surrounding-gate FET).

The first PMOS field effect transistor 552 and the first NMOS field effect transistor 555 have a common first gate structure 505a or a common first gate 505a, which first gate 505a is electrically coupled to the second electrical input B. Furthermore, the second PMOS field effect transistor 553 and the second NMOS field effect transistor 556 have a common second gate 505b, which is electrically coupled to the first electrical input A.

A first source/drain region 552a of the first PMOS field effect transistor 552 is connected to the electrical potential V_{DD} via a first connection region 507a, and a first source/drain region 553a of the second PMOS field effect transistor 553 connected in parallel with the first PMOS field effect transistor 352 is connected to the electrical potential V_{DD} via a second connection region 508a. A second source/drain region 552b of the first PMOS field effect transistor 552 and a second source/drain region 553b of the second PMOS field effect transistor 553 are electrically coupled to the electrical output Z of the NAND logic gate 550 via a third connection region 509a.

A first source/drain region 555a of the first NMOS field effect transistor 555 is connected to the electrical potential V_{SS} via a fourth connection region 507b, and a second source/drain region 555b of the first NMOS field effect transistor 555 is electrically coupled to a first source/drain region 556a of the second NMOS field effect transistor 556 connected in series with the first NMOS field effect transistor 555. A second source/drain region 556b of the second NMOS field effect transistor 556 is electrically coupled to the electrical output Z of the NAND logic gate 550 via a fifth connection region 508b.

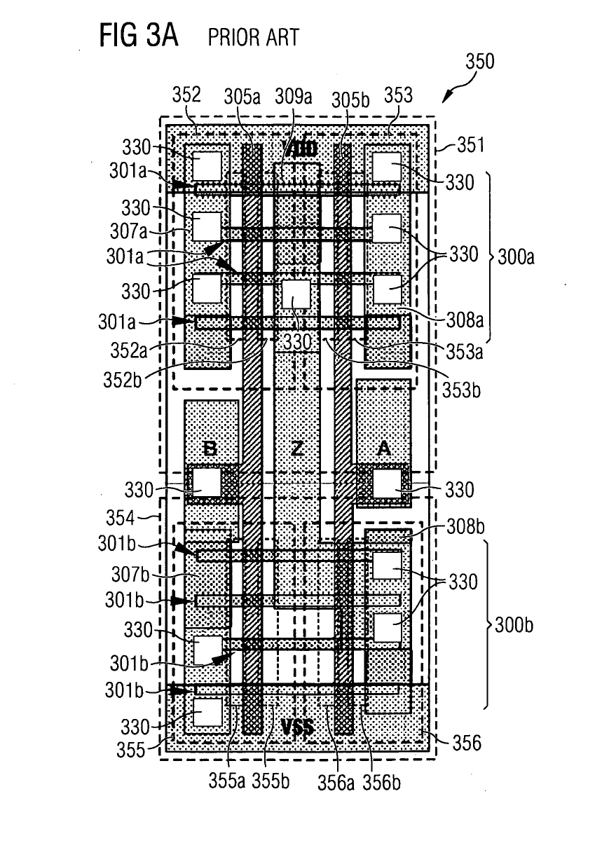

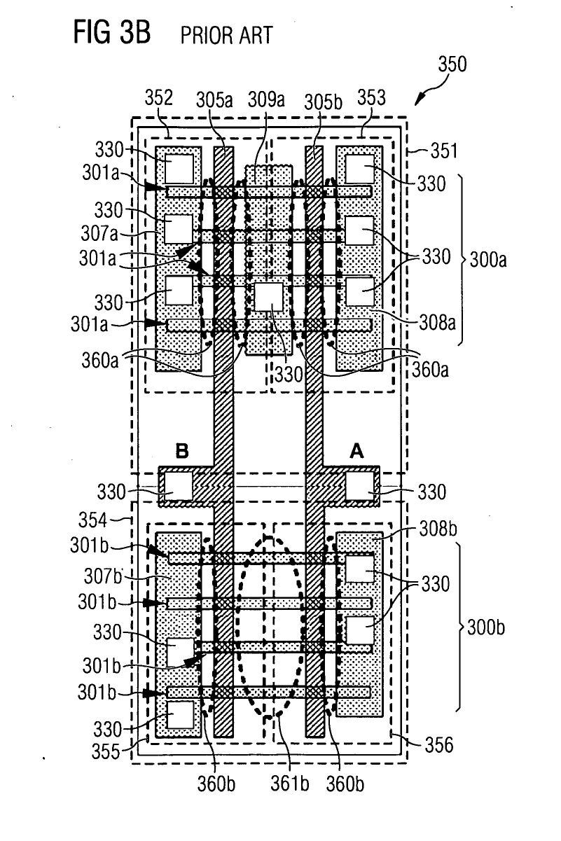

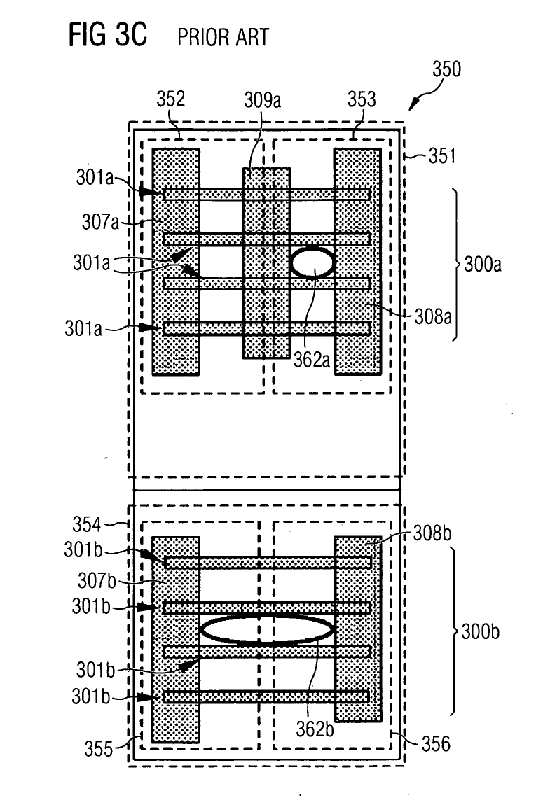

In a manner similar to the NAND logic gate 350 with conventional layout as shown in FIG. 3, in the case of the multi-fin component arrangement 550 formed as a NAND logic gate, four individual fins 501b are connected in parallel on account of the second multi-fin component partial arrangement 554 formed as an NMOS series circuit in the NMOS pull-down path. The dimensioning shown in FIG. 5 is illustrated by way of example for an NMOS/PMOS on current ratio of approximately 2:1. In the context of the invention, the multi-fin component arrangement 550 can be adapted to any NMOS/PMOS on current ratio by a suitable choice of the number of fins 501a and respectively 501b. The n/p implantations are effected as usual after the formation of the transistor gates.

In contrast to the conventional NAND logic gate 350, the multi-fin component arrangement 550 shown in FIG. 5 additionally has a dummy structure 520, which dummy structure 520 is formed as a block structure (for example, composed of silicon). The dummy structure 520 is formed below the second multi-fin structure 500b formed in the second multi-fin component partial arrangement 554. In this case, the dummy structure 520 is formed at least partially below the individual fin structures or fins 501b of the second multi-fin structure 500b. Furthermore, the dummy structure 520 is formed between the first gate 505a and the second gate 505b, that is to say clearly between the two gates of the NMOS field effect transistors 555 and 556 connected in series.

On account of the dummy structure 520 formed in the second multi-fin component partial arrangement 554, the individual fin structures or fins 501b of the second multi-fin component partial arrangement 554 formed as an NMOS series circuit have the same surroundings as the fin structures or fins 501a of the first multi-fin component partial arrangement 551 formed as a PMOS parallel circuit.

By way of example, the interspaces 562 between the individual fin structures 501a and 501b of the two multi-fin structures 500a and 500b, respectively, have a uniform size (see FIG. 5C), in contrast to the conventional arrangement 350 with interspaces 362a, 362b of different sizes as shown in FIG. 3C.

Since, in the case of the multi-fin component arrangement 550, all the multi-fin structures are identical at the level of the fin structures and source/drain regions, a very homogeneous production process can be obtained with the aid of the invention.

On account of the uniform interspaces 562 in the PMOS parallel circuit 551 and the NMOS series circuit 554, respectively, after the formation of the gate structures or gates 505a and 505b, thin silicon zones 560 (that is to say zones with thin fin structures, which fin structures include, e.g., silicon) arise between the first gate 505a and the second gate 505b, which thin silicon zones 560 likewise have a uniform, small extent (see FIG. 5B), in contrast to the silicon zones 360b, 361b having different extents in the conventional NAND logic gate 350 shown in FIG. 3B.

Since all the thin silicon zones 560 have the same small extent in the case of the multi-fin component arrangement 550, it follows that electrical characteristics (e.g., parasitic resistances and/or parasitic capacitances) of the parallel-connected PMOS field effect transistors 552, 553 and of the series-connected NMOS field effect transistors 555, 556 are adapted to one another.

Clearly, therefore, uniform transistor surroundings or transistor connection zones are formed as a result of forming the dummy structure 520, such that all the transistors or generally all the electronic components of the multi-fin component arrangement 550 have identical or similar electrical characteristics (e.g., parasitic resistances and/or parasitic capacitances).

In this case, the dummy structure 520 is formed in such a way that its size suffices for forming at least one contact hole. As a result, during the production of a multi-fin component arrangement, it is clearly possible, after forming the dummy structure, to “decide”, by forming or not forming a contact hole, whether two electronic components (e.g., transistors) are connected in parallel or connected in series.

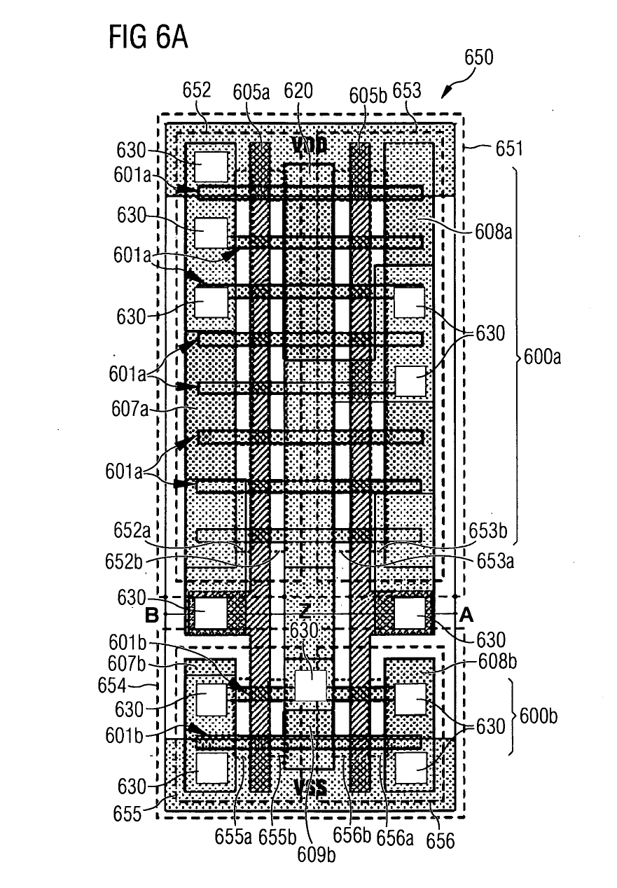

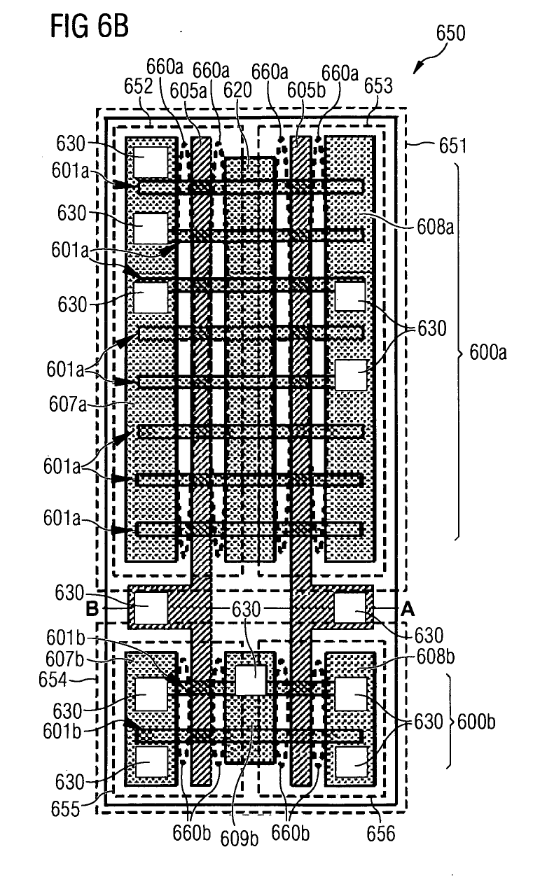

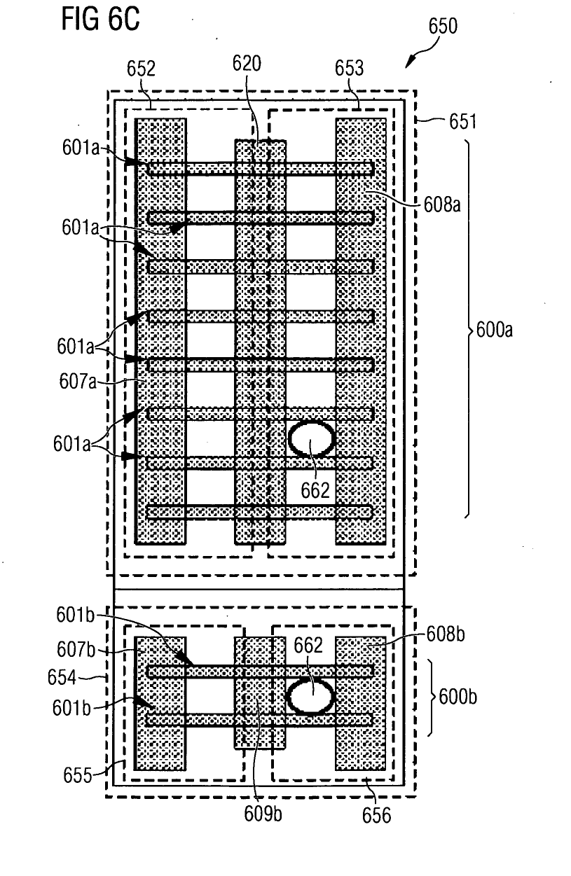

FIG. 6A, FIG. 6B and FIG. 6C show a multi-fin component arrangement 650 in accordance with a second exemplary embodiment of the invention. The multi-fin component arrangement 650 is formed as a NOR logic gate, having two electrical inputs (NOR2 logic gate), wherein a first electrical logic input signal “A” is provided at a first electrical input A and a second electrical logic input signal “B” is provided at a second electrical input B. The multi-fin component arrangement 650 formed as a NOR logic gate furthermore has an electrical output Z, an electrical logic output signal “Z= A̅+̅B̅” being provided at the electrical output.

FIG. 6A, FIG. 6B and FIG. 6C show layout illustrations of the multi-fin component arrangement 650 formed as a NOR logic gate. FIG. 6A shows the layout up to the first metallization level (metal 1), and FIG. 6B shows the layout up to and including gate and contact hole level (poly/CA), wherein the positions of individual contact holes are represented by the squares 630. FIG. 6C shows the layout after the manufacturing of the fins and source/drain regions.

The multi-fin component arrangement 650 has a first multi-fin component partial arrangement 651 and a second multi-fin component partial arrangement 654, wherein the first multi-fin component partial arrangement 651 is formed as a PMOS series circuit and the second multi-fin component partial arrangement 654 is formed as an NMOS parallel circuit.

The first multi-fin component partial arrangement 651 formed as a PMOS series circuit has two electronic components 652 and 653 formed as field effect transistor, which electronic components 652 and 653 have a common first multi-fin structure 600a. The first multi-fin component partial arrangement 651 has a first PMOS field effect transistor 652 and a second PMOS field effect transistor 653 connected in series with the first PMOS field effect transistor 652.

The second multi-fin component partial arrangement 654 formed as an NMOS parallel circuit has two electronic components 655 and 656 formed as field effect transistors, which electronic components 655 and 656 have a common second multi-fin structure 600b. The second multi-fin component partial arrangement 654 has a first NMOS field effect transistor 655 a second NMOS field effect transistor 656 connected in parallel with the first NMOS field effect transistor 655.

The first multi-fin structure 600a has eight fin structures or fins 601a connected in parallel, and the second multi-fin structure 600b has two fin structures or fins 601b connected in parallel.

Both the PMOS field effect transistors 652, 653 and the NMOS field effect transistors 655, 656 can be formed as fin field effect transistor or as multi-gate field effect transistor (for example double-gate FET, triple-gate FET, surrounding-gate FET).

The first PMOS field effect transistor 652 and the first NMOS field effect transistor 655 have a common first gate structure 605a or a common first gate 605a, which first gate 605a is electrically coupled to the second electrical input B of the NOR logic gate 650. Furthermore, the second PMOS field effect transistor 653 and the second NMOS field effect transistor 656 have a common second gate 605b, which is electrically coupled to the first electrical input A of the NOR logic gate 650.

A first source/drain region of the first PMOS field effect transistor 652 is connected to the electrical potential V_{DD} via a first connection region 607a, and a second source/drain region of the first PMOS field effect transistor 652 is electrically coupled to a first source/drain region of the second PMOS field effect transistor 653 connected in series with the first PMOS field effect transistor 652.

A second source/drain region of the second PMOS field effect transistor 653 is electrically coupled to the electrical output Z of the NOR logic gate 650 via a second connection region 608a.

A first source/drain region of the first NMOS field effect transistor 655 is connected to the electrical potential V_{SS} via a third connection region 607b, and a first source/drain region of the second NMOS field effect transistor 656 connected in parallel with the first NMOS field effect transistor 655 is connected to the electrical potential V_{SS} via a fourth connection region 608b.

A second source/drain region of the first NMOS field effect transistor 655 and a second source/drain region of the second NMOS field effect transistor 656 are electrically coupled to the electrical output Z of the NOR logic gate 650 via a fifth connection region 609b.

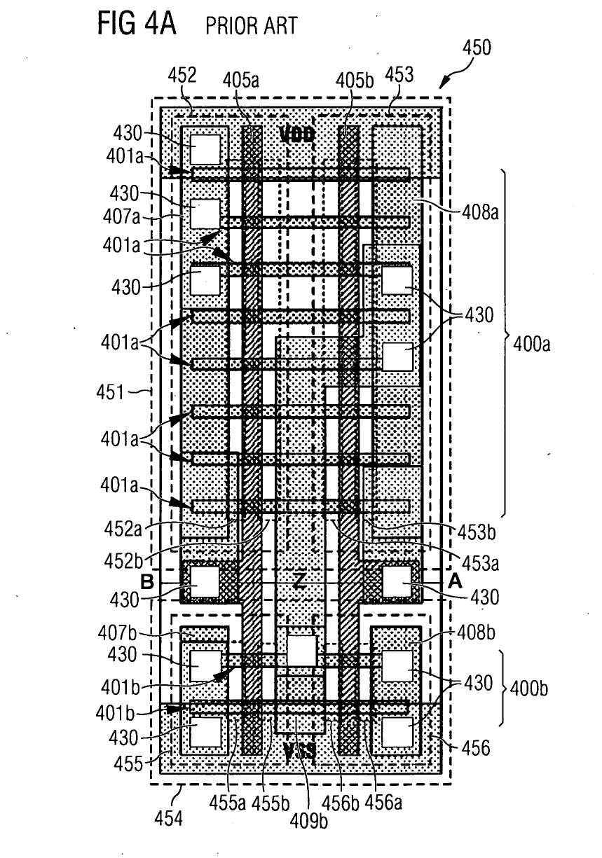

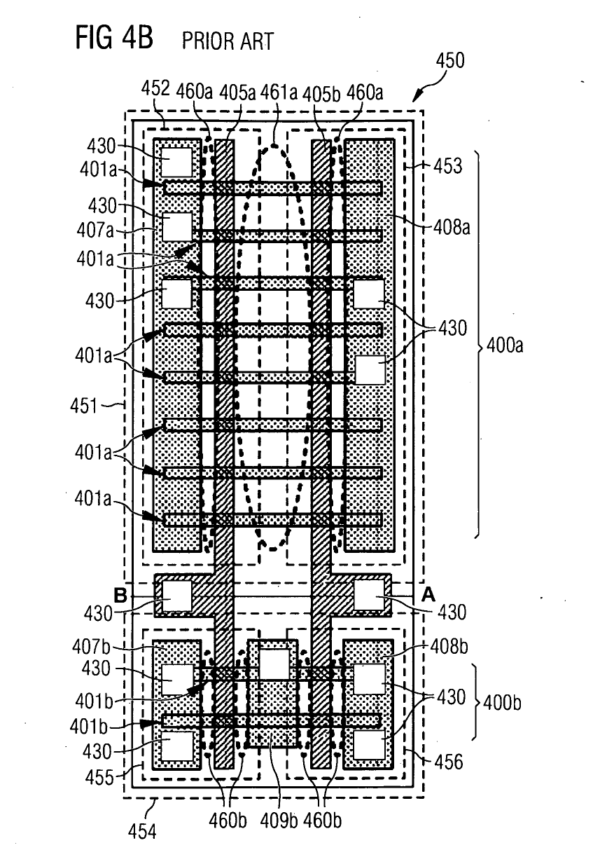

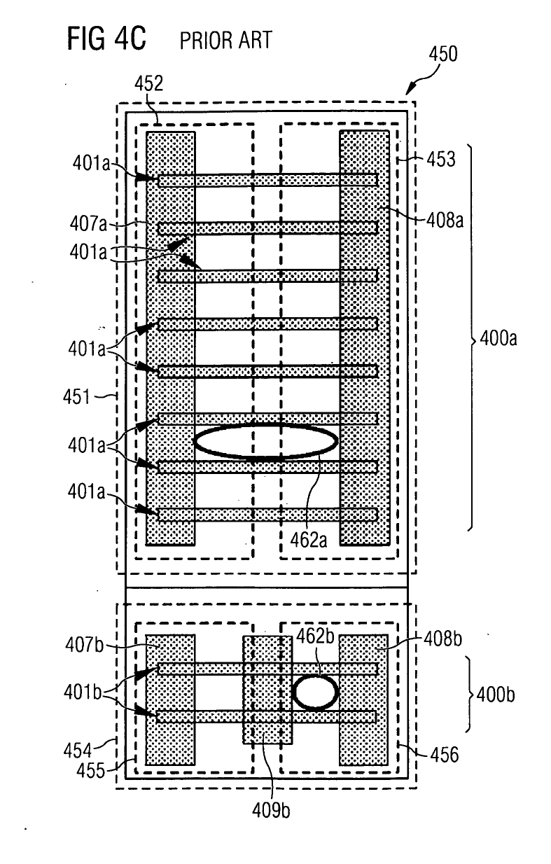

In contrast to the conventional NOR logic gate 450 shown in FIG. 4, the multi-fin component arrangement 650 formed as a NOR logic gate as shown in FIG. 6 additionally has a dummy structure 620, which dummy structure 620 is formed as a block structure (e.g., composed of silicon). The dummy structure 620 is formed below the first multi-fin structure 600a formed in the first multi-fin component partial arrangement 651. In this case, the dummy structure 620 is formed at least partly below the individual fin structures or fins 601a of the first multi-fin structure 600a. Furthermore, the dummy structure 620 is formed between the first gate 605a and the second gate 605b, that is to say clearly between the two gates of the PMOS field effect transistors 652 and 653 connected in series.

On account of the dummy structure 620 formed in the first multi-fin component partial arrangement 651, the individual fin structures or fins 601a of the first multi-fin component partial arrangements 651 formed as a PMOS series circuit have the same surroundings as the fin structures or fins 601b of the second multi-fin component partial arrangement 654 formed as an NMOS parallel circuit.

By way of example, the interspaces 662 between the individual fin structures 601a and 601b of the two multi-fin structures 600a and 600b, respectively, have the same size (see FIG. 6C), in contrast to the conventional arrangement 450 with interspaces 462a, 462b having different sizes as shown in FIG. 4C.

Since, in the case of the multi-fin component arrangement 650, all the multi-fin structures are identical at the level of the fin structures and source/drain regions, a very homogenous manufacturing process can be obtained with the aid of the invention, in a manner similar to that in the case of the multi-fin component arrangement 550 formed as a NAND logic gate.

On account of the interspaces 662 of uniform size in the multi-fin structures 600a, 600b, the thin silicon zones 660a (that is to say the zones of thin fin structures, which fin structures include silicon, for example), which thin silicon zones 660a are formed between the gates 605a, 605b and the connection regions 607a, 608a, and the dummy structure 620, along the longitudinal direction of the fin structures 601a, 601b, have the same small extent as the thin silicon zones 660b, which thin silicon zones 660b are formed between the gates 605a, 605b and the connection regions 607b, 608b and 609b. As a result, electrical characteristics (e.g. parasitic resistances and/or parasitic capacitances) of the series-connected PMOS field effect transistors 652, 653 and of the parallel-connected NMOS field effect transistors 655, 656 are adapted to one another.

In other words, electrical characteristics (e.g., parasitic resistances and/or parasitic capacitances) of all the field effect transistors 652, 653, 655 and 656 formed in the multi-fin component partial arrangements 651, 654 are adapted to one another as a result of forming the dummy structure 620.

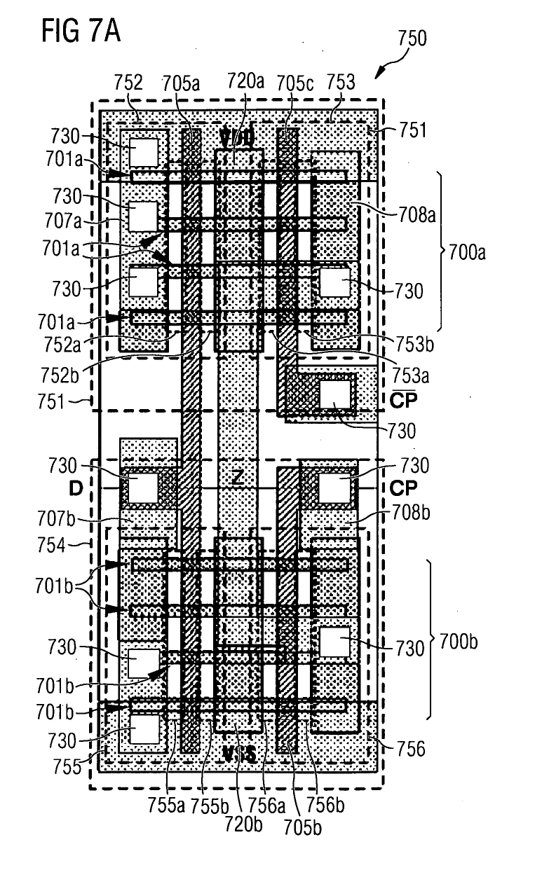

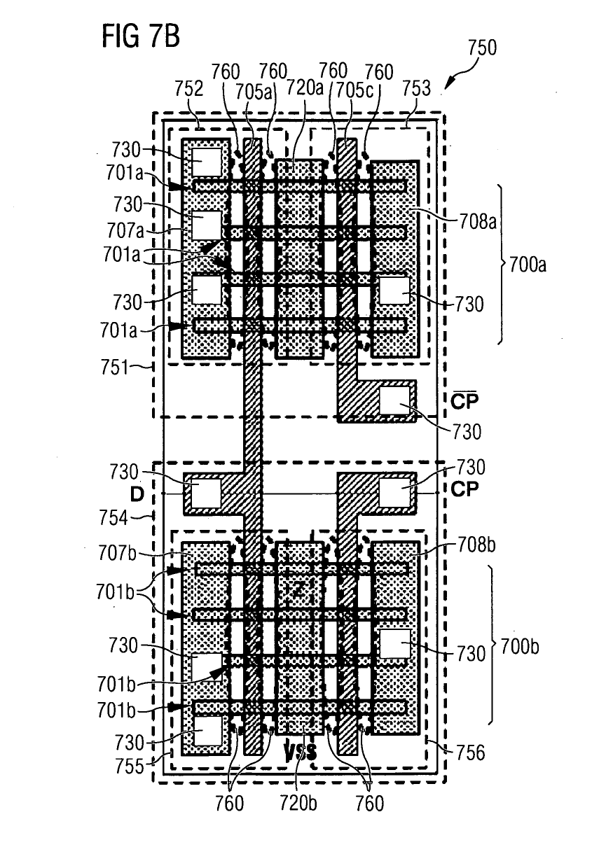

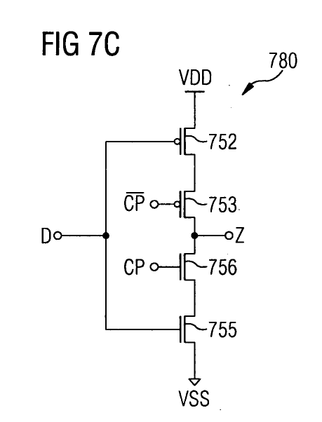

FIG. 7A and FIG. 7B show a multi-fin component arrangement 750 in accordance with a third exemplary embodiment of the invention. The multi-fin component arrangement 750 is formed as a C²MOS logic gate, having three electrical inputs, wherein an electrical logic input signal “D” is provided at a first electrical input D, a first electrical clock input signal “CP” is provided at a second electrical input CP, and a second electrical clock input signal “ C̅P̅” complementary to the first electrical clock input signal “CP” is provided at a third electrical input C̅P̅. The multi-fin component arrangement 750 formed as a C²MOS logic gate furthermore has an electrical output Z, an electrical logic output signal “Z= D̅” being provided at the electrical output.

FIG. 7A and FIG. 7B show layout illustrations of the multi-fin component arrangement 750 formed as a C²MOS logic gate. FIG. 7A shows the layout up to the first metallization level (metal 1), and FIG. 7B shows the layout up to and including gate and contact hole level (poly/CA), wherein the positions of individual contact holes are represented by the squares 730.

The multi-fin component arrangement 750 has a first multi-fin component partial arrangement 751 and a second multi-fin component partial arrangement 754, wherein the first multi-fin component partial arrangement 751 is formed as a PMOS series circuit and the second multi-fin component partial arrangement 754 is formed as an NMOS series circuit.

The first multi-fin component partial arrangement 751 formed as a PMOS series circuit has two electronic components 752 and 753 formed as field effect transistor, which electronic components 752 and 753 have a common first multi-fin structure 700a. The first multi-fin component partial arrangement 751 has a first PMOS field effect transistor 752 and a second PMOS field effect transistor 753 connected in series with the first PMOS field effect transistor 752.

The second multi-fin component partial arrangement 754 formed as an NMOS series circuit has two electronic components 755 and 756 formed as field effect transistors, which electronic components 755 and 756 have a common second multi-fin structure 700b. The second multi-fin component partial arrangement 754 has a first NMOS field effect transistor 755 and a second NMOS field effect transistor 756 connected in series with the first NMOS field effect transistor 755.

The first multi-fin structure 700a has four fin structures or fins 701a connected in parallel, and the second multi-fin structure 700b has four fin structures or fins 701b connected in parallel.

Both the PMOS field effect transistors 752, 753 and the NMOS field effect transistors 755, 756 can be formed as fin field effect transistor or as multi-gate field effect transistor (for example double-gate FET, triple-gate FET, surrounding-gate FET).

The first PMOS field effect transistor 752 and the first NMOS field effect transistor 755 have a common first gate structure 705a or a common first gate 705a, which first gate 705a is electrically coupled to the first electrical input D. Furthermore, the second NMOS field effect transistor 756 has a second gate 705b, which is electrically coupled to the second electrical input CP. Furthermore, the second PMOS field effect transistor 753 has a third gate 705c, which is electrically coupled to the third electrical input C̅P̅.

A first source/drain region 752a of the first PMOS field effect transistor 752 is connected to the electrical potential V_{DD} via a first connection region 707a, and a second source/drain region 752b of the first PMOS field effect transistor 752 is electrically coupled to a first source/drain region 753a of the second PMOS field effect transistor 753 connected in series with the first PMOS field effect transistor 752. A second source/drain region 753b of the second PMOS field effect transistor 753 is electrically coupled to the electrical output Z of the C²MOS logic gate 750 via a second connection region 708a.

A first source/drain region 755a of the first NMOS field effect transistor 755 is connected to the electrical potential V_{SS} via a third connection region 707b, and a second source/drain region 755b of the first NMOS field effect transistor 755 is electrically coupled to a first source/drain region 756a of the second NMOS field effect transistor 756 connected in series with the first NMOS field effect transistor 755. A second source/drain region 756b of the second NMOS field effect transistor 756 is electrically coupled to the electrical output Z of the C²MOS logic gate 750 via a fourth connection region 708b.

FIG. 7C shows a corresponding transistor circuit diagram 780 for the C²MOS logic gate 750 shown in FIG. 7A.

The multi-fin component arrangement 750 formed as a C²MOS logic gate as shown in FIG. 7A has a first dummy structure 720a and a second dummy structure 720b, which dummy structures 720a and 720b are formed as block structures (e.g., composed of silicon).

The first dummy structure 720a is formed below the first multi-fin structure 700a formed in the first multi-fin component partial arrangement 751, while the second dummy structure 720b is formed below the second multi-fin structure 700b formed in the second multi-fin component partial arrangement 754. In this case, the first dummy structure 720a is formed at least partly below the individual fin structures or fins 701a of the first multi-fin structure 700a, the second dummy structure 720b is formed at least partly below the individual fin structures or fins 701b of the second multi-fin structure 700b.

Furthermore, the first dummy structure 720a is formed between the first gate 705a and the third gate 705c, that is to say clearly between the two gates of the PMOS field effect transistors 752 and 753 connected in series, while the second dummy structure 720b is formed between the first gate 705a and the second gate 705b, that is to say clearly between the two gates of the NMOS field effect transistors 755 and 756 connected in series.

On account of the first dummy structure 720a formed in the first multi-fin component partial arrangement 751 and the second dummy structure 720b formed in the second multi-fin component partial arrangement 754, the individual fin structures or fins 701a of the first multi-fin component partial arrangement 751 formed as a PMOS series circuit and the individual fins 701b of the second multi-fin component partial arrangement 754 formed as an NMOS series circuit have the same surroundings.

In particular, as in the previous exemplary embodiments, the interspaces between the individual fin structures of the two multi-fin structures 700a and 700b have a uniform size.

On account of the dummy structures 720a and 720b, all the thin silicon zones 760 (see FIG. 7B) (that is to say the zones with thin fins, which fins comprise, e.g., silicon) formed in the multi-fin component partial arrangements 751, 754, which thin silicon zones 760 are formed between the gates 705a, 705b, 705c and the connection regions 707a, 708a, 708b, and dummy structures 720a, 720b, have approximately the same small extent, such that all the electronic components formed in the multi-fin component partial arrangements 751, 754, that is to say the PMOS field effect transistors 752, 753 and the NMOS field effect transistors 755, 756, have at least approximately the same low parasitic resistance and/or approximately the same parasitic capacitance.

In other words, with the aid of the dummy structures 720a, 720b, uniform transistor surroundings are obtained and electrical characteristics of the transistors such as, for example, parasitic resistances and/or parasitic capacitances are adapted to one another and in addition positively influenced.

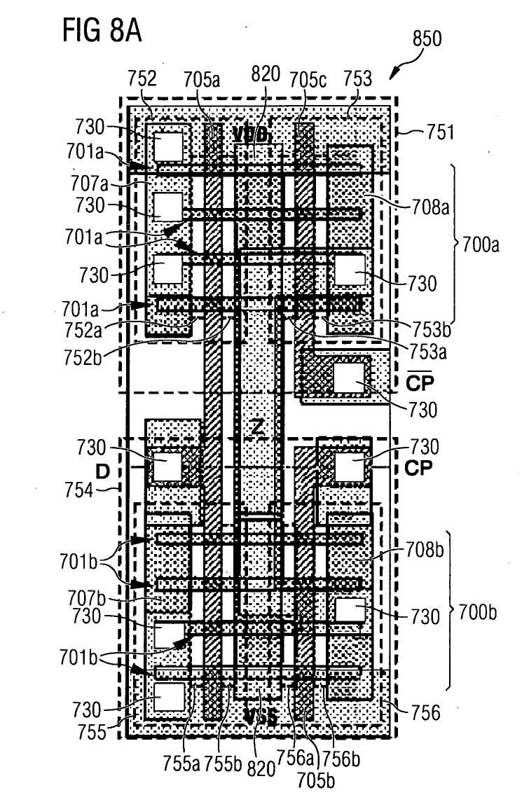

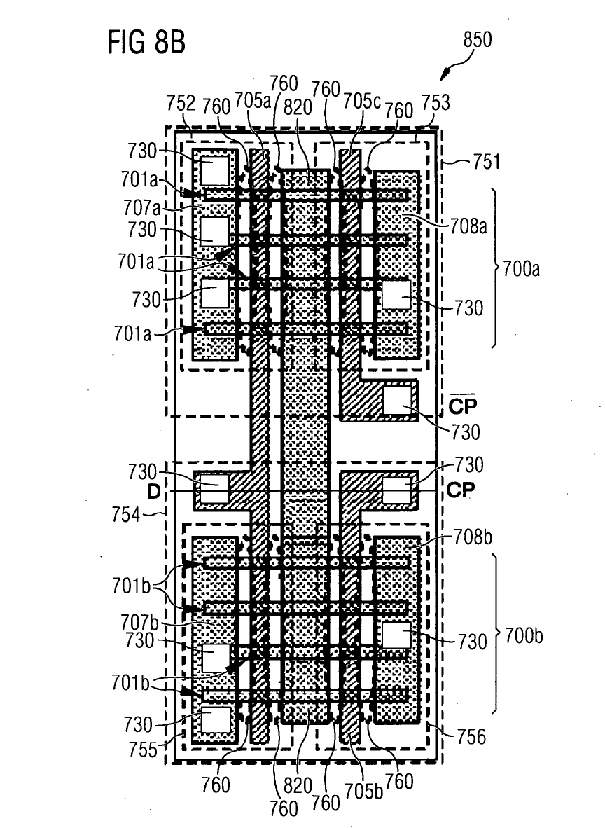

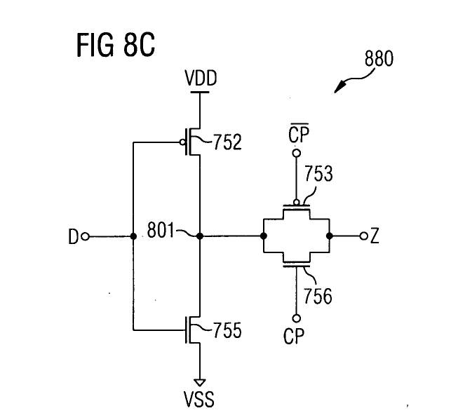

FIG. 8A and FIG. 8B show a multi-fin component arrangement 850 in accordance with a fourth exemplary embodiment of the invention. The multi-fin component arrangement 850 is formed as a transmission gate having three electrical inputs, wherein an electrical logic input signal “D” is provided at a first electrical input D, a first electrical clock input signal “CP” is provided at a second electrical input CP, and a second electrical clock input signal “ C̅P̅” complementary to the first electrical clock input signal “CP” is provided at a third electrical input C̅P̅. The multi-fin component arrangement 850 formed as a transmission gate furthermore has an electrical output Z, an electrical logic output signal “Z= D̅” being provided at the electrical output.

FIG. 8A and FIG. 8B show layout illustrations of the multi-fin component arrangement 850 formed as a transmission gate. FIG. 8A shows the layout up to the first metallization level (metal 1), and FIG. 8B shows the layout up to and including gate and contact hole level (poly/CA), wherein the positions of individual contact holes are represented by the squares 730.

The multi-fin component arrangement 850 formed as a transmission gate differs from the multi-fin component arrangement 750 formed as a C²MOS logic gate as shown in FIG. 7A by virtue of the fact that, in the case of the transmission gate 850, a single dummy structure 820 is formed below the two multi-fin structures 700a and 700b. In other words, the first multi-fin component partial arrangement 751 and the second multi-fin component partial arrangement 754 have a common dummy structure 820, which dummy structure 820 is formed between the series-connected PMOS field effect transistors 752, 753 of the first multi-fin component partial arrangement 751 formed as a PMOS series circuit and between the series-connected NMOS field effect transistors 755, 756 of the second multi-fin component partial arrangement 754 formed as an NMOS series circuit.

The dummy structure 820 is formed as a block structure composed of silicon, wherein the block structure is formed at least partly below the first multi-fin structure 700a and at least partly below the second multi-fin structure 700b.

FIG. 8C shows a corresponding transistor circuit diagram 880 for the multi-fin component arrangement 850 formed as transmission gate as shown in FIG. 8A. The internal electrical node 801 at the output of the inverter, which inverter is formed by the first PMOS field effect transistor 752 and the first NMOS field effect transistor 755, is embodied as a continuous silicon zone, i.e., a common dummy structure 820, in the multi-fin component arrangement 850. This results in an area-efficient arrangement in which, by way of example, a vertical metal 1 line is saved. The multi-fin component arrangement 850 shown in FIG. 8A can be used as an alternative, SOI-specific arrangement.

Forming the dummy structure 820 in the multi-fin component arrangement 850 formed as a transmission gate results in the advantages already mentioned in connection with the previous exemplary embodiments, such as, for example, uniform (low) parasitic resistances and/or capacitances of the field effect transistors 752, 753, 755 and 756 formed in the multi-fin component partial arrangements 751, 754.

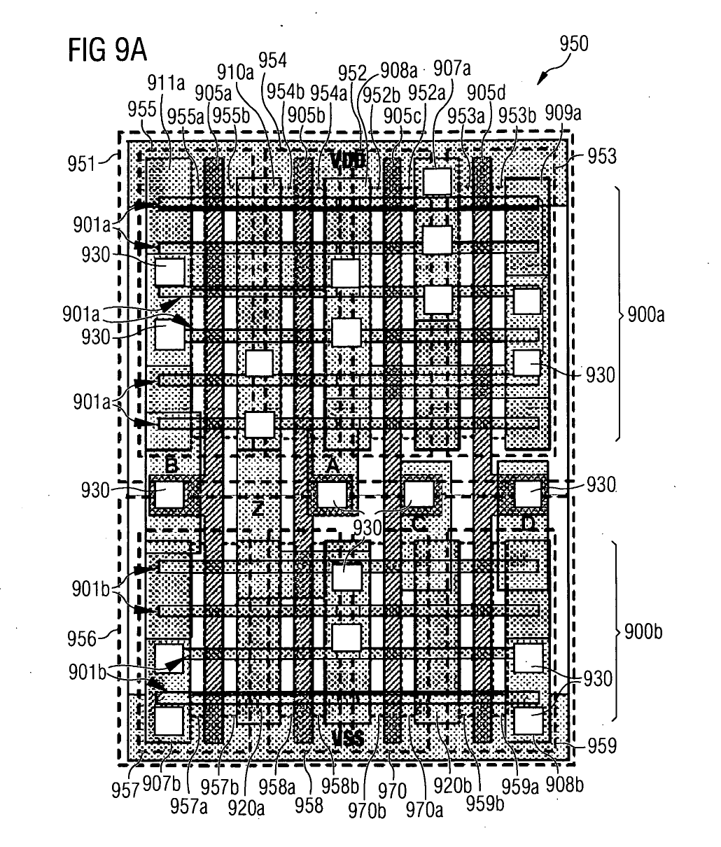

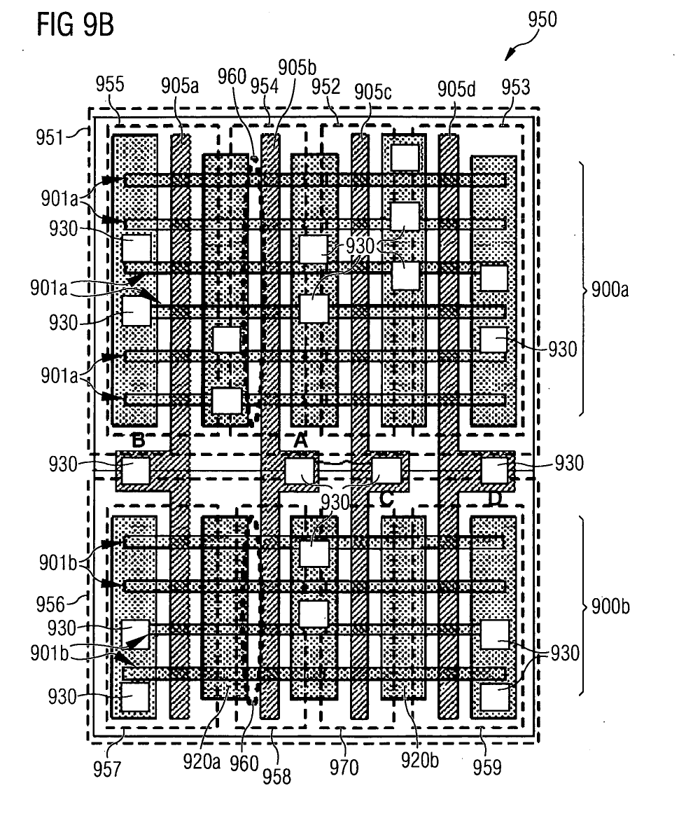

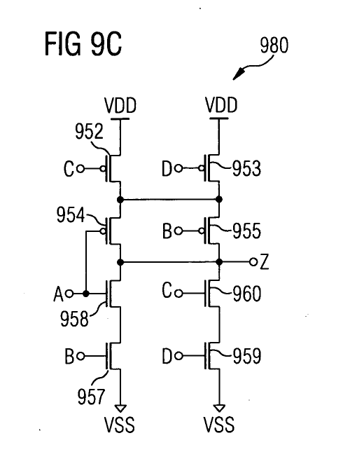

FIG. 9A and FIG. 9B show a multi-fin component arrangement 950 in accordance with a fifth exemplary embodiment of the invention. The multi-fin component arrangement 950 is formed as an AND-OR inverting logic gate (AND-OR inverter, AOI) having four electrical inputs, wherein a first electrical logic input signal “A” is provided at a first electrical input A, a second electrical logic input signal “B” is provided at a second electrical input B, a third electrical logic input signal “C” is provided at a third electrical input C, and a fourth electrical logic input signal “D” is provided at a fourth electrical input D. The multi-fin component arrangement 950 formed as an AND-OR inverting logic gate furthermore has an electrical output Z, an electrical logic output signal “Z= A̅B̅+̅C̅D̅” being provided at the electrical output.

FIG. 9A and FIG. 9B show layout illustrations of the multi-fin component arrangement 950 formed as an AND-OR inverting logic gate. FIG. 9A shows the layout up to the first metallization level (metal 1), and FIG. 9B shows the layout up to and including gate and contact hole level (poly/CA), wherein the positions of individual contact holes are represented by the squares 930.

The multi-fin component arrangement 950 has a first multi-fin component partial arrangement 951 and a second multi-fin component partial arrangement 956, wherein the first multi-fin component partial arrangement 951 is formed as a PMOS circuit and the second multi-fin component partial arrangement 956 is formed as an NMOS circuit.

The first multi-fin component partial arrangement 951 formed as a PMOS circuit has four electronic components 952, 953, 954 and 955 formed as field effect transistor, which electronic components 952, 953, 954 and 955 have a common first multi-fin structure 900a. The first multi-fin component partial arrangement 951 has a first PMOS field effect transistor 952 and a second PMOS field effect transistor 953 connected in parallel with the first PMOS field effect transistor 952. Furthermore, the first multi-fin component partial arrangement 951 has a third PMOS field effect transistor 954 and a fourth PMOS field effect transistor 955 connected in parallel with the third PMOS field effect transistor 954. The parallel-connected field effect transistors 952 and 953 are additionally connected in series with the parallel-connected field effect transistors 954 and 955.

Clearly, therefore, the first multi-fin component partial arrangement 951 is formed as a PMOS series connection of in each case two parallel-connected PMOS field effect transistors, i.e., the parallel-connected PMOS field effect transistors 952 and 953 and respectively 954 and 955.

The second multi-fin component partial arrangement 956 formed as an NMOS circuit has four electronic components 957, 958, 959 and 970 formed as field effect transistor, which electronic components 957, 958, 959 and 970 have a common second multi-fin structure 900b. The second multi-fin component partial arrangement 956 has a first NMOS field effect transistor 957 and a second NMOS field effect transistor 958 connected in series with the first NMOS field effect transistor 957. Furthermore, the second multi-fin component partial arrangement 956 has a third NMOS field effect transistor 959 and a fourth NMOS field effect transistor 970 connected in series with the third NMOS field effect transistor 959. The series-connected field effect transistors 957 and 958 are additionally connected in parallel with the series-connected field effect transistors 959 and 970.

Clearly, therefore, the second multi-fin component partial arrangement 956 is formed as an NMOS parallel connection of in each case two series-connected NMOS field effect transistors, i.e., the series-connected NMOS field effect transistors 957 and 958 and respectively 959 and 970.

The first multi-fin structure 900a has six fin structures or fins 901a connected in parallel, and the second multi-fin structure 900b has four fin structures or fins 901b connected in parallel.

Both the PMOS field effect transistors 952, 953, 954 and 955 and the NMOS field effect transistors 957, 958, 959, 970 can be formed as fin field effect transistor or as multi-gate field effect transistor (for example, double-gate FET, triple-gate FET, surrounding-gate FET).

The fourth PMOS field effect transistor 955 and the first NMOS field effect transistor 957 have a common first gate structure 905a or a common first gate 905a, which first gate 905a is electrically coupled to the second electrical input B. The third PMOS field effect transistor 954 and the second NMOS field effect transistor 958 have a common second gate 905b, which is electrically coupled to the first electrical input A. The first PMOS field effect transistor 952 and the fourth NMOS field effect transistor 970 have a common third gate 905c, which is electrically coupled to the third electrical input C. Furthermore, the second PMOS field effect transistor 953 and the third NMOS field effect transistor 959 have a common fourth gate 905d, which is electrically coupled to the fourth electrical input D.

A first source/drain region 952a of the first PMOS field effect transistor 952 and a first source/drain region 953a of the second PMOS field effect transistor 953 are connected to the electrical potential V_{DD} via a first connection region 907a. A second source/drain region 952b of the first PMOS field effect transistor 952 is connected to a second connection region 908a, and a second source/drain region 953b of the second PMOS field effect transistor 953 connected in parallel with the first PMOS field effect transistor 952 is connected to a third connection region 909a. The second connection region 908a and the third connection region 909a are electrically coupled to one another, such that the second source/drain region 952b of the first PMOS field effect transistor 952 and the second source/drain region 953b of the second PMOS field effect transistor are likewise electrically coupled to one another.

The second source/drain region 952b of the first PMOS field effect transistor 952 and the second source/drain region 953b of the second PMOS field effect transistor 953, the second source/drain region 953b being electrically coupled to the second source/drain region 952b of the first PMOS field effect transistor 952, are furthermore electrically coupled via the second connection region 908a to a first source/drain region 954a of the third PMOS field effect transistor 954, and via a fourth connection region 910a to a first source/drain region 955a of the fourth PMOS field effect transistor 955 connected in parallel with the third PMOS field effect transistor 954.

A second source/drain region 954b of the third PMOS field effect transistor 954 and a second source/drain region 955b of the fourth PMOS field effect transistor 955 connected in parallel with the third PMOS field effect transistor 954 are electrically coupled to the electrical output Z of the AND-OR inverting logic gate 950 via a fifth connection region 911a.

A first source/drain region 957a of the first NMOS field effect transistor 957 is connected to the electrical potential V_{SS} via a sixth connection region 907a, and a first source/drain region 959a of the third NMOS field effect transistor 959 is connected to the electrical potential V_{SS} via a seventh connection region 908b. A second source/drain region 957b of the first NMOS field effect transistor 957 is electrically coupled to a first source/drain region 958a of the second NMOS field effect transistor 958 connected in series with the first NMOS field effect transistor 957, and a second source/drain region 959b of the third NMOS field effect transistor 959 is electrically coupled to a first source/drain region 970a of the fourth NMOS field effect transistor 970 connected in series with the NMOS field effect transistor 959.

A second source/drain region 958b of the second NMOS field effect transistor 958 and a second source/drain region 970b of the fourth NMOS field effect transistor 970 are electrically coupled to the electrical output Z of the AND-OR inverting logic gate 950 via an eighth connection region 909b.

FIG. 9C shows a corresponding transistor circuit diagram 980 for the AND-OR inverting logic gate 950 shown in FIG. 9A and FIG. 9B.

The multi-fin component arrangement 950 formed as an AND-OR inverting logic gate as shown in FIG. 9A and FIG. 9B has a first dummy structure 920a and a second dummy structure 920b, which dummy structures 920a and 920b are formed as block structures (e.g., composed of silicon).

The first dummy structure 920a and the second dummy structure 920b are formed below the second multi-fin structure 900b formed in the second multi-fin component partial arrangement 956. In this case, the first dummy structure 920a and the second dummy structure 920b are formed at least partly below the individual fin structures or fins 901b of the second multi-fin structure 900b.

Furthermore, the first dummy structure 920a is formed between the first gate 905a and the second gate 905b, that is to say clearly between the two gates of the two NMOS field effect transistors 957 and 958 connected in series, while the second dummy structure 920b is formed between the third date 905c and the fourth gate 905d, that is to say clearly between the two gates of the two NMOS field effect transistors 959 and 970 connected in series.

On account of the first dummy structure 920a and second dummy structure 920b formed in the second multi-fin component partial arrangement 956, the individual fin structures or fins 901b of the second multi-fin component partial arrangement 956 have the same surroundings as the fin structures 901a of the first multi-fin component partial arrangement 951.

In particular, as in the previous exemplary embodiments, the interspaces between the fin structures 901a, 901b of the two multi-fin structures 900a and 900b have a uniform size.

It can be discerned from FIG. 9B that all the thin silicon zones 960 (that is to say the zones with thin fin structures composed of silicon) formed in the first multi-fin component partial arrangement 951 and the second multi-fin component partial arrangement 956, which thin silicon zones 960 are formed between the gates and the connection regions (in the first multi-fin component partial arrangement 951 and the second multi-fin component partial arrangement 956) and respectively between the gates and the dummy structures (in the second multi-fin component partial arrangement 956), along the longitudinal direction of the fin structures, have approximately the same small extent (for the sake of clarity in the illustration only two thin silicon zones 960 are highlighted by dashed lines in FIG. 9B), such that electrical characteristics (e.g., parasitic resistances and/or parasitic capacitances) of the PMOS field effect transistors 952, 953, 954, 955 and of the NMOS field effect transistors 957, 958, 959, 970 are adapted to one another with the aid of the dummy structures 920a, 920b.

Representative CMOS logic structures or CMOS logic gates have been shown above as possible exemplary embodiments of the invention. In this case, all the transistors have substantially identical multi-fin structures and differ only in the number of fins in the PMOS pull-up paths and the NMOS pull-down paths. The diverse logic functions of these exemplary embodiments show that the design technology presented here is suitable as a basis for a CMOS standard cell library.

In a method for manufacturing a multi-fin component arrangement in accordance with one of the previous exemplary embodiments, firstly the fin structures (fin) of the multi-fin structures, the connection regions and the at least one dummy structure are formed on a substrate (e.g., silicon-on-insulator substrate, SOI), see, e.g., the layout illustrations of FIGS. 5C and 6C, which show layouts of multi-fin component arrangements up to the level of the fin structures. The fins and/or the connection regions and/or the at least one dummy structure can be formed using deposition methods (e.g., chemical vapor deposition, CVD) and/or patterning methods (e.g., etching methods and lithography methods). The fin structures, connection regions and dummy structures can include silicon material.

In a subsequent method step, the gate structures or gates are formed, for example, by a deposition method. The gates can be formed as polysilicon gates. The formation of the transistor gates is followed by the formation of the source/drain regions in the fin structures, for example by introducing doping atoms (n-type doping and/or p-type doping). The source/drain regions can be doped using an implantation method (e.g., ion implantation).

Contact holes (vias) are formed for making electrical contact with the connection regions, see, e.g., the layout illustrations of FIGS. 5B, 6B, 7B, 8B and 9B, which show layouts of multi-fin component arrangements up to and including gate and contact hole level (poly/CA).

By forming a first metallization layer, electrical contact can be made with the connection regions, see, e.g., the layout illustrations of FIGS. 5A, 6A, 7A, 8A and 9A, which show layouts of multi-fin component arrangements up to and including the first metallization level (metal 1).

In the exemplary embodiments shown, the transistor gates for NMOS transistors and PMOS transistors were arranged exclusively in a vertical form throughout with equidistant spacing. This arrangement has lithographic advantages and avoids rounding effects, for example, which rounding effects can occur at possible corners in the case of angular gates. If, during production, so-called phase shift masks are used for improving the resolution, then the transistor gates have to be arranged on a fixed grid with equidistant spacing. Since this method is currently already being employed in 65-nm CMOS technology, this type of transistor gate arrangement is also presupposed for multi-gate transistors.

What is claimed is:

1. A multi-fin component arrangement, comprising:
a plurality of multi-fin component partial arrangements,
wherein each of the multi-fin component partial arrangements has a plurality of electronic components, each electronic component having a multi-fin structure;
wherein at least one multi-fin component partial arrangement has at least one dummy structure, the at least one dummy structure being formed between at least two of the electronic components formed in the at least one multi-fin component partial arrangement; and
wherein the at least one dummy structure is formed in such a way that electrical characteristics of the electronic components formed in the multi-fin component partial arrangements are adapted to one another.

2. The multi-fin component arrangement as claimed in claim 1, wherein the at least one dummy structure is formed in such a way that it adapts parasitic resistances of the electronic components formed in the multi-fin component partial arrangements to one another and/or adapts parasitic capacitances of the electronic components formed in the multi-fin component partial arrangements to one another.

3. The multi-fin component arrangement as claimed in claim 1, wherein the at least one dummy structure is formed as a block structure, the block structure being formed at least partly below at least one of the multi-fin structures of the electronic components formed in the multi-fin component partial arrangements.

4. The multi-fin component arrangement as claimed in claim 3, wherein the block structure comprises silicon material.

5. The multi-fin component arrangement as claimed in claim 1, wherein at least one multi-fin component partial arrangement has at least two electronic components connected in parallel.

6. The multi-fin component arrangement as claimed in claim 1, wherein at least one multi-fin component partial arrangement has at least two electronic components connected in series.

7. The multi-fin component arrangement as claimed in claim 1, wherein at least one of the electronic components is formed as a field effect transistor.

8. The multi-fin component arrangement as claimed in claim 6, wherein the at least one dummy structure is formed between the at least two electronic components connected in series.

9. The multi-fin component arrangement as claimed in claim 7, wherein the at least one dummy structure is formed between gate structures of at least two field effect transistors connected in series.

10. The multi-fin component arrangement as claimed in claim 9, wherein at least one of the field effect transistors is formed as a fin field effect transistor and/or as a multi-gate field effect transistor.

11. The multi-fin component arrangement as claimed in claim 7, wherein at least one of the field effect transistors is formed as a MOS field effect transistor.

12. The multi-fin component arrangement as claimed in claim 11, wherein the multi-fin component arrangement is formed as a CMOS circuit arrangement, wherein:
in at least one multi-fin component partial arrangement, at least one of the electronic components formed as a MOS field effect transistor is formed as a PMOS field effect transistor; and
in the at least one multi-fin component partial arrangement, at least one of the electronic components formed as a MOS field effect transistor is formed as an NMOS field effect transistor.

13. The multi-fin component arrangement as claimed in claim 12, wherein the multi-fin component arrangement is formed as a logic gate circuit.

14. The multi-fin component arrangement as claimed in claim 13, wherein the logic gate circuit is formed as:
a NAND logic gate; or
a NOR logic gate; or
a C²MOS logic gate; or
a CMOS transmission gate; or
an AND-OR inverting logic gate.

15. The multi-fin component arrangement as claimed in claim 3, wherein the block structure has a size, that is suitable for forming at least one contact hole.

16. The multi-fin component arrangement as claimed in claim 1, wherein the multi-fin structures of the electronic components formed in the multi-fin component partial arrangements have at least two fin structures.

17. The multi-fin component arrangement as claimed in claim 16, wherein the fin structures have a length of 60 nm to 800 nm, a width of 10 nm to 50 nm and a height of 20 nm to 80 nm.

18. The multi-fin component arrangement as claimed in claim 17, wherein the fin structures have a pitch of 20 nm to 200 nm.

19. A method for manufacturing a multi-fin component arrangement, the method comprising:
forming a plurality of multi-fin component partial arrangements, wherein each of the multi-fin component partial arrangements has a plurality of electronic components, which electronic components have a multi-fin structure;
forming at least one dummy structure in at least one multi-fin component partial arrangement, which at least one dummy structure is formed between at least two of the electronic components formed in the at least one multi-fin component partial arrangement, wherein the at least one dummy structure is formed in such a way that electrical characteristics of the electronic components formed in the multi-fin component partial arrangements are adapted to one another with the aid of the at least one dummy structure.
